(19) United States
(12) Patent Application Publication
(10) Pub. No.: US 2012/0092047 A1
(43) Pub. Date: Apr. 19, 2012

(54) POWER-ON RESET CIRCUIT

(75) Inventors: Jiun-Chiang Chen, Hsinchu County (TW); Han-Pang Wang, Tainan County (TW)

(73) Assignee: UPI SEMICONDUCTOR CORP., Hsinchu County (TW)

(21) Appl. No.: 13/004,036

(22) Filed: Jan. 11, 2011

(30) Foreign Application Priority Data
Oct. 19, 2010 (TW) 99135607

(51) Int. Cl. H03L 7/00

(52) U.S. Cl. 327/143

(57) ABSTRACT

A power-on reset circuit including a voltage divider, a first transistor and a second transistor is provided. The voltage divider is electrically connected between a first source voltage and a first ground voltage, and generates a sensing voltage. A drain of the first transistor is electrically connected to a second source voltage, and a gate and a source of the first transistor are connected to each other. A conductive channel of the second transistor is the same with that of the first transistor, and a type of the second transistor is different from a type of the first transistor. Furthermore, a drain of the second transistor is electrically connected to the source of the first transistor. A gate of the second transistor receives the sensing voltage. A source of the second transistor is electrically connected to a second ground voltage.

### CROSS-REFERENCE TO RELATED APPLICATION

This application claims the priority benefit of Taiwan application serial no. 99135607, filed on Oct. 19, 2010. The entirety of the above-mentioned patent application is hereby incorporated by reference herein and made a part of this specification.

### BACKGROUND

1. Field of the Invention

The invention relates to a power-on reset circuit. Particularly, the invention relates to a power-on reset circuit capable of reducing temperature influence.

2. Description of Related Art

Regarding an electronic circuit, setting of an initial state thereof is very important. Generally, at an initial stage for supplying power to the electronic circuit, the electronic circuit is in an unstable state. Therefore, a power-on reset (POR) circuit is required to be designed to reset the state of the circuit during a power-on process, so as to ensure the initial state of electronic circuit to be in a predetermined state.

FIG. 1 is a circuit diagram of a conventional POR circuit. Referring to FIG. 1, the POR circuit 100 produces an output voltage proportional to a power voltage VD₁ through a p-channel transistor MP₁₁ and an n-channel transistor MN₁₁. Moreover, p-channel transistors MP₁₂-MP₁₄ and n-channel transistors MN₁₂-MN₁₄ form a comparison circuit. In this way, when the power voltage VD₁ is continually increased to a first predetermined voltage, the POR circuit 100 may produce a reset signal S₁₁ with a high logic level through an inverter 110. On the other hand, when the power voltage VD₁ is continually decreased to a second predetermined voltage, the POR circuit 100 may produce the reset signal S₁₁ with a low logic level.

A magnitude of the first predetermined voltage is determined by threshold voltages of the p-channel transistors MP₁₂ and MP₁₃, and a magnitude of the second predetermined voltage is determined by threshold voltages of the n-channel transistors MN₁₂ and MN₁₃. However, since a threshold voltage of a transistor is shifted due to temperature influence, the first predetermined voltage and the second predetermined voltage used for determining the power voltage VD₁ are also varied along with temperature, which may cause a miss operation of the circuit.

FIG. 2 is a circuit diagram of another conventional POR circuit. Referring to FIG. 2, the POR circuit 200 produces a sensing voltage VA₂ proportional to a power voltage VD₂ through a voltage-dividing effect of resistors R21 and R22. Moreover, a bandgap reference circuit 210 is used for generating a reference voltage VR₂ non-related to temperature. A comparator 220 compares the reference voltage VR₂ and the sensing voltage VA₂. In this way, when the sensing voltage VA₂ is greater than the reference voltage VR₂, the POR circuit 200 produces a reset signal S₂₁ with a high logic level.

Since the POR circuit 200 uses the reference voltage VR₂ non-related to temperature as a reference to compare the sensing voltage VA₂, influence of temperature to the circuit is avoided. However, circuit structures of the bandgap reference circuit 210 and the comparator 220 are relatively complicated, so that a layout area and production cost of the POR circuit 200 are correspondingly increased.

Therefore, how to effectively prevent the temperature from influencing the circuit and simultaneously optimize the layout area of the circuit is an important issue for designing a POR circuit.

### SUMMARY OF THE INVENTION

The invention is directed to a power-on reset (POR) circuit, which can reduce influence of temperature to the circuit.

The invention is directed to a POR circuit, which can reduce a layout area and production cost of the circuit.

The invention provides a power-on reset (POR) circuit including a voltage divider, a first transistor and a second transistor. The voltage divider is electrically connected between a first power voltage and a first ground voltage, and generates a sensing voltage. A drain of the first transistor is electrically connected to a second power voltage, and a gate and a source of the first transistor are electrically connected to each other. Conductive channels of the second transistor and the first transistor are the same, and types thereof are different. Furthermore, a drain of the second transistor is electrically connected to the source of the first transistor. A gate of the second transistor receives the sensing voltage. A source of the second transistor is electrically connected to a second ground voltage.

In an embodiment of the invention, the POR circuit further includes an inverter, and the inverter is electrically connected to the drain of the second transistor.

In an embodiment of the invention, the POR circuit further includes a third transistor. Conductive channel and types of the third transistor and the second transistor are the same. Moreover, a drain and a gate of the third transistor are electrically connected to the source of the second transistor, and a source of the third transistor is electrically connected to the second ground voltage.

The invention provides a power-on reset (POR) circuit including a voltage divider, X first transistors and Y second transistors. The voltage divider is electrically connected between a first power voltage and a first ground voltage, and generates a sensing voltage. Gates of the X first transistors are electrically connected to each other, and a drain of a 1st first transistor is electrically connected to a second power voltage, a source of an i-th first transistor is electrically connected to a drain of an (i+1)-th first transistor, and a source and a gate of an X-th first transistor are electrically connected to a node, where X is an integer greater than 1, i is an integer and 1≦i≦(X−1). Moreover, conductive channels of the Y second transistors and the X first transistors are the same, and types thereof are different. Furthermore, gates of the Y second transistors are electrically connected and receive the sensing voltage, a drain of a 1st second transistor is electrically connected to the node, a source of a j-th second transistor is electrically connected to a drain of a (j+1)-th transistor, and a source of a Y-th second transistor is electrically connected to a second ground voltage, where Y is an integer greater than 1, j is an integer and 1≦j≦(Y−1).

In an embodiment of the invention, the POR circuit further includes Z third transistors. Conductive channel of the Z third transistors and the Y second transistors are the same, and types thereof are the same. Moreover, gates of the Z third transistors are electrically connected, a drain and a gate of a 1st third transistor are electrically connected to a source of a Y-th second transistor, a source of a k-th third transistor is electrically connected to a drain of a (k+1)-th third transistor, and a source of a Z-th third transistor is electrically connected to the second ground voltage, where Z is an integer greater than 1, k is an integer and 1≦k≦(Z−1).

According to the above descriptions, in the invention, transistors with the same conductive channel and different types are used to generate a trip point voltage non-related to temperature. Moreover, the POR circuit of the invention compares the sensing voltage proportional to the power voltage according to the trip point voltage non-related to temperature. In this way, the POR circuit of the invention can reduce influence of temperature to the circuit, and avails reducing a layout area and production cost of the circuit.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit diagram of a conventional power-on reset (POR) circuit.

FIG. 2 is a circuit diagram of another conventional POR circuit.

FIG. 3 is a circuit diagram of a POR circuit according to an embodiment of the invention.

FIG. 4 is a circuit diagram of a POR circuit according to another embodiment of the invention.

FIG. 5 is a circuit diagram of a POR circuit according to still another embodiment of the invention.

FIG. 6 is a circuit diagram of a POR circuit according to yet another embodiment of the invention.

FIG. 7 is a circuit diagram of a POR circuit according to still another embodiment of the invention.

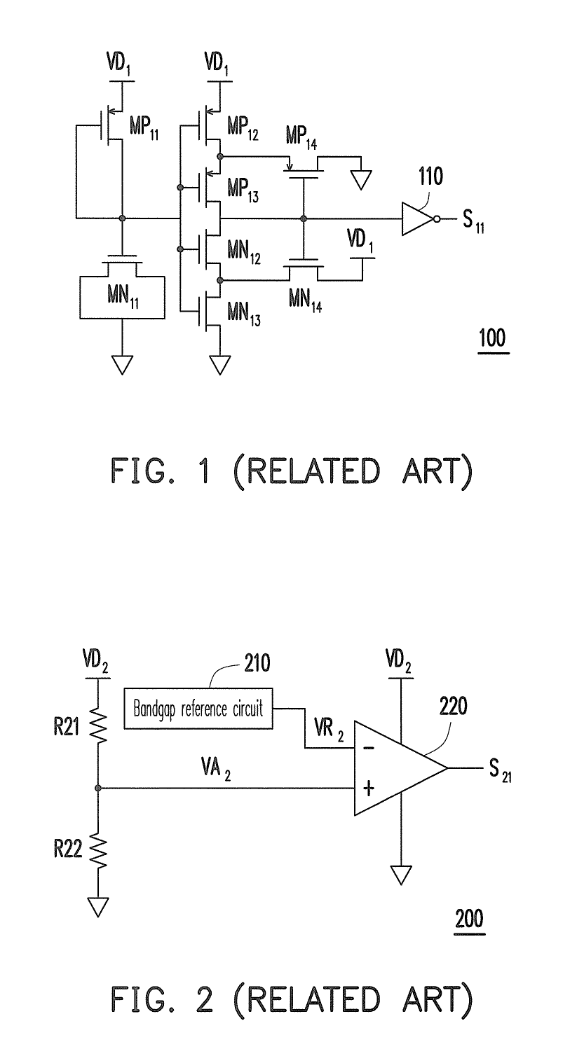

### DETAILED DESCRIPTION OF DISCLOSED EMBODIMENTS

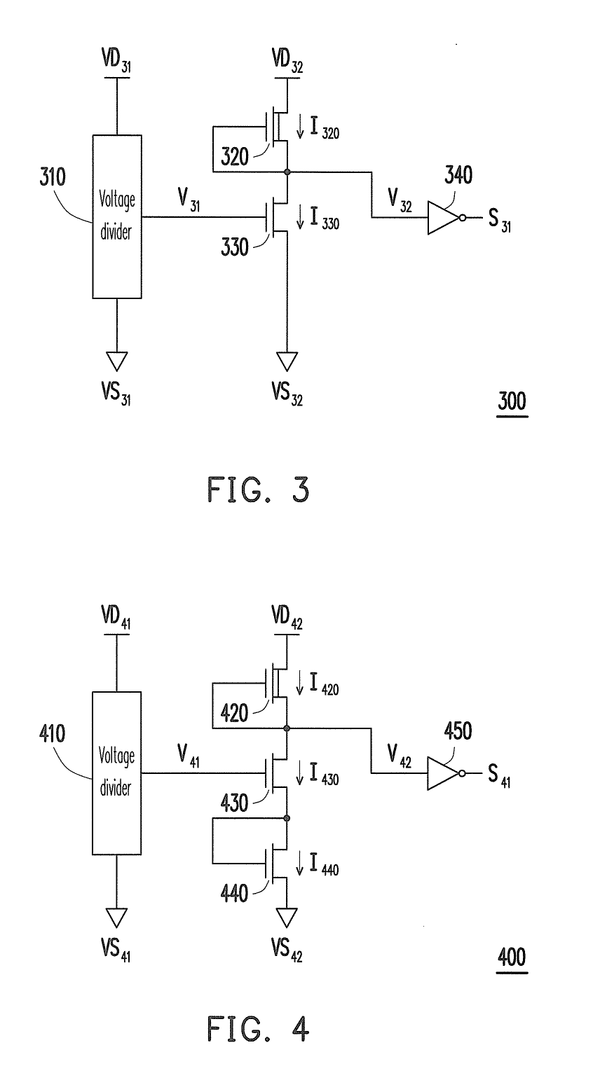

FIG. 3 is a circuit diagram of a power-on reset (POR) circuit according to an embodiment of the invention. Referring to FIG. 3, the POR circuit 300 includes a voltage divider 310, a transistor 320, a transistor 330 and an inverter 340. The transistor 320 and the transistor 330 have the same conductive channel and different types.

For example, conductive channels of the transistors include an n-channel and a p-channel, and in the present embodiment, n-channel transistors are used to implement the transistor 320 and the transistor 330. Moreover, types of the transistors include a depletion type and an enhancement type, and in the present embodiment, a depletion type transistor is used to implement the transistor 320, and an enhancement type transistor is used to implement the transistor 330. In other words, in the present embodiment, the transistor 320 is a depletion type n-channel transistor, and the transistor 330 is an enhancement type n-channel transistor. However, implementations of the transistors of the present embodiment are not used to limit the invention, and as long as the transistor 320 and the transistor 330 have the same conductive channel and different types, it is considered to be within the scope of the invention.

Referring to FIG. 3, the voltage divider 310 is electrically connected between a first power voltage VD₃₁ and a first ground voltage VS₃₁. On the other hand, a drain of the transistor 320 is electrically connected to a second power voltage VD₃₂, and a gate and a source of the transistor 320 are electrically connected. Moreover, a drain of the transistor 330 is electrically connected to the source of the transistor 320, a gate of the transistor 330 receives a sensing voltage V₃₁, and a source of the transistor 330 is electrically connected to a second ground voltage VS₃₂. The first power voltage VD₃₁ can be equal to the second power voltage VD₃₂, and the first ground voltage VS₃₁ can be equal to the second ground voltage VS₃₂.

In view of operation, the voltage divider 310 can be formed by a plurality of voltage-dividing elements connected in series. For example, a plurality of resistors connected in series may form the voltage divider 310. In this way, the voltage divider 310 can adjust a level of the sensing voltage V₃₁ according to a variation of the first power voltage VD₃₁. The sensing voltage V₃₁ is gradually increased as the first power voltage VD₃₁ is increased. Moreover, when the sensing voltage V₃₁ is gradually increased and is higher than a trip point voltage, the transistor 330 is turned on, so that a level of a node voltage V₃₂ is pulled down to approach the second ground voltage VS₃₂. Comparatively, the inverter 340 may generate a reset signal S₃₁ with a high logic level according to the node voltage V₃₂. On the other hand, the sensing voltage V₃₁ is gradually decreased as the first power voltage VD₃₁ is decreased. When the sensing voltage V₃₁ is gradually decreased and is lower than the trip point voltage, the transistor 330 is turned off, so that a level of the node voltage V₃₂ is pulled up to approach the second power voltage VD₃₂. Now, the inverter 340 may generate the reset signal S₃₁ with a low logic level according to the node voltage V₃₂.

It should be noticed that the inverter 340 is mainly used to provide a logic signal inverted to the node voltage V₃₂. Therefore, in an actual application, those skilled in the art can remove the inverter 340 and takes the node voltage V₃₂ as the reset signal according to an actual design requirement. For example, when the inverter 340 is removed, the node voltage V₃₂ with a level closed to the second ground voltage VS₃₂ can serve as the reset signal with the low logic level, and the node voltage V₃₂ with a level closed to the second power voltage VD₃₂ can serve as the reset signal with the high logic level.

Moreover, in the present embodiment, in the POR circuit 300 takes the trip point voltage as a reference to compare the sensing voltage V₃₁. In order to fully convey the spirit of the invention to those skilled in the art, equations of the trip point voltage are deduced according to circuit characteristics of the POR circuit 300, and in following equations, the trip point voltage is represented by VP₃.

First, it is assumed that the transistor 330 is in a turned on state, and a current I₃₂₀ flowing through the transistor 320 and a current I₃₃₀ flowing through the transistor 330 are accordingly calculated. Here, since the transistor 320 is the depletion type n-channel transistor, and the gate and the source of the transistor 320 are electrically connected, the current I₃₂₀ flowing through the transistor 320 is represented by a following equation (1-1):

$${I}_{320} = \frac{1}{2} {μ}_{n , DEP} {C}_{ox} \frac{{W}_{320}}{{L}_{320}} {( {V}_{gs , 320} - {V}_{t , DEP} )}^{2} \approx \frac{1}{2} {μ}_{n , DEP} {C}_{ox} \frac{{W}_{320}}{{L}_{320}} {( {V}_{t , DEP} )}^{2} \qquad ( 1 \text{-} 1 )$$

Where, μ_{n,DEP} and V_{t,DEP} are respectively a carrier mobility and a threshold voltage of the depletion type n-channel transistor, Cₒₓ is an oxide capacitance of a unit area, W₃₂₀ and L₃₂₀ are respectively a width and a length of the conductive channel of the transistor 320, and V_{gs,320} is a voltage difference between the gate and the source of the transistor 320.

Moreover, since the transistor 330 is the enhancement type n-channel transistor, the current I₃₃₀ flowing through the transistor 320 is represented by a following equation (1-2):

$${I}_{330} = \frac{1}{2} {μ}_{n , ENH} {C}_{ox} \frac{{W}_{330}}{{L}_{330}} {( {V}_{gs , 330} - {V}_{t , ENH} )}^{2} \qquad ( 1 \text{-} 2 )$$

Where, μ_{n,ENH} and V_{t,ENH} are respectively a carrier mobility and a threshold voltage of the enhancement type n-channel transistor, Cₒₓ is an oxide capacitance of a unit area, W₃₃₀ and L₃₃₀ are respectively a width and a length of the conductive channel of the transistor 330, and V_{gs,330} is a voltage difference between the gate and the source of the transistor 330.

Moreover, the trip point voltage VP₃ is equal to the gate-source voltage V_{gs,330} of the transistor 330, so that the trip point voltage VP₃ can be deduced as a following equation (1-3) according to the equation (1-2):

$${VP}_{3} = {V}_{gs , 330} = {V}_{t , ENH} + \sqrt{\frac{{I}_{330}}{\frac{1}{2} {μ}_{n , ENH} {C}_{ox} \frac{{W}_{330}}{{L}_{330}}}} \qquad ( 1 \text{-} 3 )$$

Moreover, since the transistor 320 and the transistor 330 are connected in series, the current I₃₂₀ flowing through the transistor 320 is equal to the current I₃₃₀ flowing through the transistor 330. Therefore, if the current I₃₃₀ in the equation (1-3) is replaced by the equation (1-1) related to the current I₃₂₀, and assuming μ_{n,ENH} is equal to μ_{n,DEP}, a following equation (1-4) is deduced:

$$\begin{matrix}{VP}_{3} = {V}_{t , ENH} + \sqrt{\frac{{I}_{320}}{\frac{1}{2} {μ}_{n , ENH} {C}_{ox } \frac{{W}_{330}}{{L}_{330}}}} \\ = {V}_{t , ENH} + \sqrt{\frac{\frac{1}{2} {μ}_{n , DEP} {C}_{ox} \frac{{W}_{320}}{{L}_{320}}}{\frac{1}{2} {μ}_{n , ENH} {C}_{ox} \frac{{W}_{330}}{{L}_{330}}}} \times {V}_{t , DEP} \\ \approx {V}_{t , ENH} + \sqrt{\frac{\frac{{W}_{320}}{{L}_{320}}}{\frac{{W}_{330}}{{L}_{330}}}} \times {V}_{t , DEP }\end{matrix} \qquad ( 1 \text{-} 4 )$$

If the lengths and widths of the conductive channels of the transistor 320 and the transistor 330 are all the same, the equation (1-4) can be simplified as a following equation (1-5):

VP₃=V_{t,ENH}+V_{t,DEP} (1-5)

Referring to the equation (1-5), it is known that since the threshold voltage V_{t,DEP} of the depletion type transistor has a positive temperature coefficient and the threshold voltage V_{t,ENH} of the enhancement type transistor has a negative temperature coefficient, the trip point voltage VP₃ of the present embodiment has a characteristic of non-related to temperature. Moreover, compared to the conventional POR circuit 200 of FIG. 2, the POR circuit 300 can prevent the temperature from influencing the circuit without using complicated electronic devices (for example, a bandgap reference circuit and a comparator), so that the present embodiment avails reducing a layout area and production cost of the circuit.

FIG. 4 is a circuit diagram of a POR circuit according to another embodiment of the invention. Referring to FIG. 4, the POR circuit 400 includes a voltage divider 410, a transistor 420, a transistor 430, a transistor 440 and an inverter 450. The transistor 420 and the transistor 430 have the same conductive channel and different types, and the transistor 430 and the transistor 440 have the same conductive channel and the same type. For example, in the present embodiment, the transistor 420 is a depletion type n-channel transistor, and the transistor 430 and the transistor 440 are enhancement type n-channel transistors. However, implementations of the transistors of the present embodiment are not used to limit the invention.

Referring to FIG. 4, the voltage divider 410 is electrically connected between a first power voltage VD₄₁ and a first ground voltage VS₄₁. On the other hand, a drain of the transistor 420 is electrically connected to a second power voltage VD₄₂, and a gate and a source of the transistor 420 are electrically connected. Moreover, a drain of the transistor 430 is electrically connected to the source of the transistor 420, and a gate of the transistor 430 receives a sensing voltage V₄₁. A drain and a gate of the transistor 440 are electrically connected to a source of the transistor 430, and a source of the transistor 440 is electrically connected to a second ground voltage VS₄₂. The first power voltage VD₄₁ can be equal to the second power voltage VD₄₂, and the first ground voltage VS₄₁ can be equal to the second ground voltage VS₄₂.

In view of operation, similar to the embodiment of FIG. 3, the voltage divider 410 can be formed by a plurality of voltage-dividing elements connected in series, and can adjust a level of the sensing voltage V₄₁ according to a variation of the first power voltage VD₄₁. When the sensing voltage V₄₁ is gradually increased and is higher than a trip point voltage, the transistor 430 is turned on, so that a level of a node voltage V₄₂ is pulled down to approach the second ground voltage VS₄₂. On the other hand, when the sensing voltage V₄₁ is gradually decreased and is lower than the trip point voltage, the transistor 430 is turned off, so that the level of the node voltage V₄₂ is pulled up to approach the second power voltage VD₄₂. Moreover, the inverter 450 is mainly used to provide a logic signal inverted to the node voltage V₄₂. Therefore, in an actual application, those skilled in the art can determine whether or not to use the inverter 450 according to an actual design requirement.

A main difference between the present embodiment and the embodiment of FIG. 3 is that in the embodiment of FIG. 3, two transistors 320 and 330 are connected in series, though in the present embodiment, three transistors 420-440 are connected in series. However, in view of a whole operation, the POR circuit 400 of the present embodiment still takes the trip point voltage as a reference to compare the sensing voltage V₄₁, and the trip point voltage has the characteristic of non-related to temperature. In order to fully convey the spirit of the invention to those skilled in the art, equations of the trip point voltage are deduced according to circuit characteristics of the POR circuit 400, and in following equations, the trip point voltage is represented by VP₄.

First, it is assumed that the transistor 430 is in a turned on state, and currents I₄₂₀-I₄₄₀ respectively flowing through the transistors 420-440 are accordingly calculated. The currents I₄₂₀-I₄₄₀ are represented by following equations (2-1)-(2-3):

$$\begin{matrix}{I}_{420} = \frac{1}{2} {μ}_{n , DEP} {C}_{ox} \frac{{W}_{420}}{{L}_{420}} {( {V}_{gs , 420} - {V}_{t , DEP} )}^{2} \approx \frac{1}{2} {μ}_{n , DEP} {C}_{ox} \frac{{W}_{420}}{{L}_{420}} {( {V}_{t , DEP} )}^{2} & ( 2 \text{-} 1 ) \\ {I}_{430} = \frac{1}{2} {μ}_{n , ENH} {C}_{ox} \frac{{W}_{430}}{{L}_{430}} {( {V}_{gs , 430} - {V}_{t , ENH} )}^{2} & ( 2 \text{-} 2 ) \\ {I}_{440} = \frac{1}{2} {μ}_{n , ENH} {C}_{ox} \frac{{W}_{430}}{{L}_{430}} {( {V}_{gs , 440} - {V}_{t , ENH} )}^{2} & ( 2 \text{-} 3 )\end{matrix}$$

Where, μ_{n,DEP} and V_{t,DEP} are respectively a carrier mobility and a threshold voltage of the depletion type n-channel transistor, Cₒₓ is an oxide capacitance of a unit area, W₄₂₀ and L₄₂₀ are respectively a width and a length of the conductive channel of the transistor 420, and V_{gs,420} is a voltage difference between the gate and the source of the transistor 420. μ_{n,ENH} and V_{t,ENH} are respectively a carrier mobility and a threshold voltage of the enhancement type n-channel transistor, W₄₃₀ and L₄₃₀ are respectively a width and a length of the conductive channel of the transistor 430, and V_{gs,430} is a voltage difference between the gate and the source of the transistor 430. W₄₄₀ and L₄₄₀ are respectively a width and a length of the conductive channel of the transistor 440, and V_{gs,440} is a voltage difference between the gate and the source of the transistor 440.

Moreover, the trip point voltage VP₄ is equal to a sum of the gate-source voltage V_{gs,430} of the transistor 430 and the gate-source voltage V_{gs,440} of the transistor 440, so that the trip point voltage VP₄ can be deduced as a following equation (2-4) according to the equations (2-2) and (2-3):

$$\begin{matrix}{VP}_{4} = {V}_{gs , 430} + {V}_{gs , 440} \\ = 2 \times {V}_{t , ENH} + \sqrt{\frac{{I}_{430}}{\frac{1}{2} {μ}_{n , ENH} {C}_{ox} \frac{{W}_{430}}{{L}_{430}}}} + \sqrt{\frac{{I}_{440}}{\frac{1}{2} {μ}_{n , ENH} {C}_{ox} \frac{{W}_{440}}{{L}_{440}}}}\end{matrix} \qquad ( 2 \text{-} 4 )$$

Moreover, since the transistors 420-440 are connected in series, I₄₂₀=I₄₃₀=I₄₄₀. Therefore, if the equation (2-1) of the current I₄₂₀ is used to replace the currents I₄₃₀ and I₄₄₀ in the equation (2-4), and assuming μ_{n,ENH} is equal to μ_{n,DEP}, a following equation (2-4) is deduced:

$$\begin{matrix}{VP}_{4} = 2 \times {V}_{t , ENH} + \sqrt{\frac{{I}_{420}}{\frac{1}{2} {μ}_{n , ENH} {C}_{ox} \frac{{W}_{430}}{{L}_{430}}}} + \sqrt{\frac{{I}_{420}}{\frac{1}{2} {μ}_{n , ENH} {C}_{ox} \frac{{W}_{440}}{{L}_{440}}}} \\ = 2 \times {V}_{t , ENH} + ( \sqrt{\frac{\frac{1}{2} {μ}_{n , DEP} {C}_{ox} \frac{{W}_{420}}{{L}_{420}}}{\frac{1}{2} {μ}_{n , ENH} {C}_{ox} \frac{{W}_{430}}{{L}_{430}}}} + \sqrt{\frac{\frac{1}{2} {μ}_{n , DEP} {C}_{ox} \frac{{W}_{420}}{{L}_{420}}}{\frac{1}{2} {μ}_{n , ENH} {C}_{ox} \frac{{W}_{440}}{{L}_{440}}}} ) \times \\ {V}_{t , DEP} \\ \approx 2 \times {V}_{t , ENH} + ( \sqrt{\frac{\frac{{W}_{420}}{{L}_{420} }}{\frac{{W}_{430}}{{L}_{430}}}} + \sqrt{\frac{\frac{{W}_{420}}{{L}_{420}}}{\frac{{W}_{440}}{{L}_{440}}}} ) \times {V}_{t , DEP}\end{matrix} \qquad ( 2 \text{-} 5 )$$

If the lengths and widths of the conductive channels of the transistors 420-440 are all the same, the equation (2-5) can be simplified as a following equation (2-6):

VP₄=2×(V_{t,ENH}+V_{t,DEP}) (2-6)

Referring to the equation (2-6), it is known that the trip point voltage VP₄ has the characteristic of non-related to temperature, so that influence of the temperature to the circuit can be reduced. Moreover, the POR circuit 400 of the present embodiment avails reducing a layout area and production cost of the circuit.

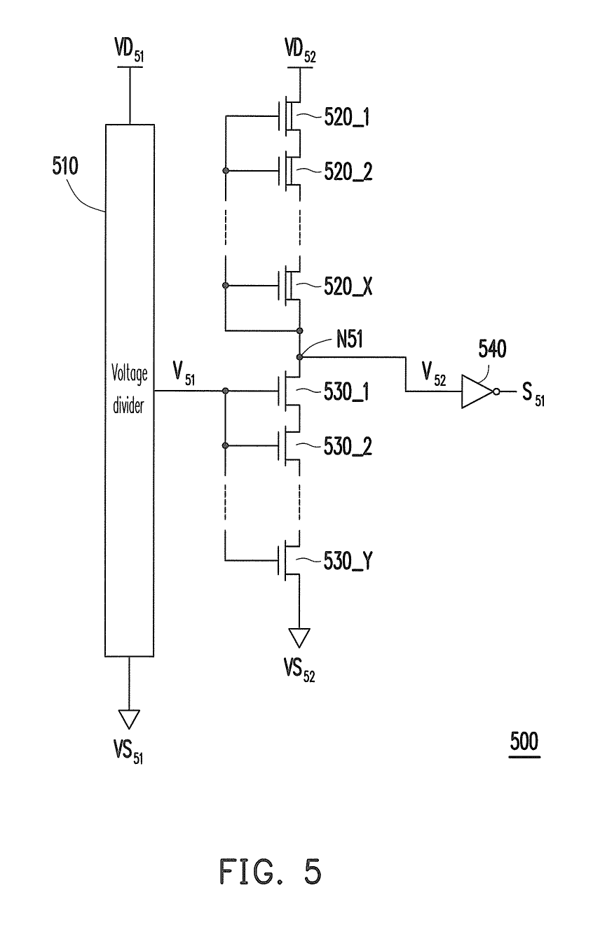

FIG. 5 is a circuit diagram of a POR circuit according to still another embodiment of the invention. Referring to FIG. 5, the POR circuit 500 includes a voltage divider 510, X transistors 520_1-520_X, Y transistors 530_1-530_Y and an inverter 540, where X and Y are integers greater than 1. The transistors 520_1-520_X are depletion type n-channel transistors, and the transistors 530_1-530_Y are enhancement type n-channel transistors. However, implementations of the transistors of the present embodiment are not used to limit the invention, and as long as the transistors 520_1-520_X and the transistors 530_1-530_Y have the same conductive channel and different transistor types, it is considered to be within the scope of the invention.

The present embodiment is an extension of the embodiment of FIG. 3, and in the present embodiment, X transistors 520_1-520_X connected in series are used to replace the transistor 320 of FIG. 3, and Y transistors 530_1-530_Y connected in series are used to replace the transistor 330 of FIG. 3. Therefore, gates of the transistors 520_1-520_X are electrically connected. Moreover, a source of an i-th transistor 520_{—}i is electrically connected to a drain of an (i+1)-th transistor 520_(i+1), a drain of a 1st transistor 520_1 is electrically connected to a second power voltage VD₅₂, and a source and a gate of an X-th transistor 520_X are electrically connected to a node N51, where i is an integer and 1≦i≦(X−1). On the other hand, gates of the transistors 530_1-530_Y are electrically connected. Moreover, a source of a j-th transistor 530_{—}j is electrically connected to a drain of a (j+1)-th transistor 530_(j+1), a drain of the 1st transistor 530_1 is electrically connected to the node N51, and a source of a Y-th transistor 530_Y is electrically connected to a second ground voltage VS₅₂, where j is an integer and 1≦j≦(Y−1).

Similar to the embodiment of FIG. 3, the voltage divider 510 is electrically connected between a first power voltage VD₅₁ and a first ground voltage VS₅₁, and adjusts a level of a sensing voltage V₅₁ according to a variation of the first power voltage VD₅₁. When the sensing voltage V₅₁ is gradually increased and is higher than a trip point voltage, the transistors 530_1-530_Y are turned on, so that a level of a node voltage V₅₂ is pulled down to approach the second ground voltage VS₅₂. On the other hand, when the sensing voltage V₅₁ is gradually decreased and is lower than the trip point voltage, the transistors 530_1-530_Y are turned off, so that the level of the node voltage V₅₂ is pulled up to approach the second power voltage VD₅₂. Moreover, the inverter 540 is mainly used to provide a logic signal inverted to the node voltage V₅₂. Therefore, in an actual application, those skilled in the art can determine whether or not to use the inverter 540 according to an actual design requirement.

Moreover, the POR circuit 500 of the present embodiment still takes the trip point voltage as a reference to compare the sensing voltage V₅₁, and an equation of the trip point voltage VP₅ of the present embodiment can be deduced as a following equation (3-1) according the deduction flow of the embodiment of FIG. 3:

$${VP}_{5} = {V}_{t , ENH} + \sqrt{\frac{\frac{{W}_{520}}{( X \times {L}_{520} )}}{\frac{{W}_{530}}{( Y \times {L}_{530} )}}} \times {V}_{t , DEP} \qquad ( 3 \text{-} 1 )$$

Where, V_{t,ENH} is a threshold voltage of the enhancement type n-channel transistor, and V_{t,DEP} is a threshold voltage of the depletion type n-channel transistor. W₅₂₀ and L₅₂₀ are respectively a width and a length of the conductive channel of each of the transistors 520_1-520_X, and W₅₃₀ and L₅₃₀ are respectively a width and a length of the conductive channel of each of the transistors 530_1-530_Y.

Here, if the lengths and widths of the conductive channels of the transistors 520_1-520_X and the transistors 530_1-530_Y are all the same, and X=Y, the equation (3-1) can be simplified as a following equation (3-2):

VP₅=V_{t,ENH}+V_{t,DEP} (3-2)

Referring to the equation (3-2), it is known that the trip point voltage VP₅ has the characteristic of non-related to temperature, so that influence of the temperature to the circuit can be reduced. Moreover, the POR circuit 500 of the present embodiment avails reducing a layout area and production cost of the circuit. In addition, it should be noticed that in an actual application, the numbers of the transistors X and Y can be different, and the lengths and the widths of the conductive channels of the transistors can also be different. In other words, those skilled in the art can arbitrarily adjust the lengths and the widths of the conductive channels and the numbers of the transistors according to an actual design requirement, so as to facilitate adjustment of the trip point voltage VP₅ and the temperature coefficient.

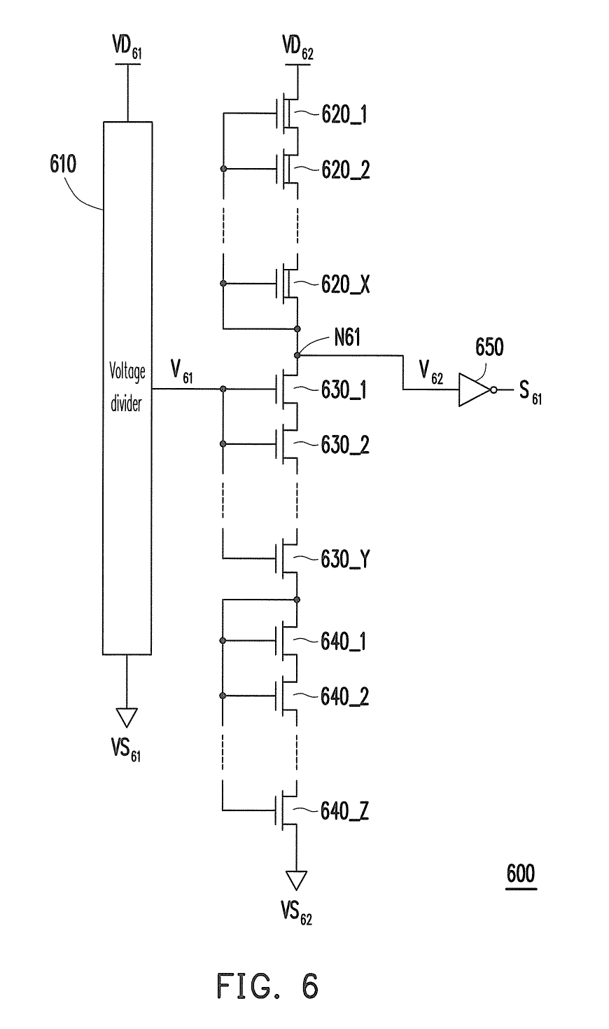

FIG. 6 is a circuit diagram of a POR circuit according to yet another embodiment of the invention. Referring to FIG. 6, the POR circuit 600 includes a voltage divider 610, X transistors 620_1-620_X, Y transistors 630_1-630_Y, Z transistors 640_1-640_Z and an inverter 650, where X, Y and Z are integers greater than 1. The transistors 620_1-620_X are depletion type n-channel transistors, and the transistors 630_1-630_Y and the transistors 640_1-640_Z are enhancement type n-channel transistors. However, implementations of the transistors of the present embodiment are not used to limit the invention, and as long as the transistors 620_1-620_X and the transistors 630_1-630_Y have the same conductive channel and different transistor types, and the transistors 630_1-630_Y and the transistors 640_1-640_Z have the same conductive channel and the same transistor types, it is considered to be within the scope of the invention.

The present embodiment is an extension of the embodiment of FIG. 4, and in the present embodiment, X transistors 620_1-620_X connected in series are used to replace the transistor 420 of FIG. 4, Y transistors 630_1-630_Y connected in series are used to replace the transistor 430 of FIG. 4, and Z transistors 640_1-640_Z connected in series are used to replace the transistor 440 of FIG. 4. Therefore, gates of the transistors 620_1-620_X are electrically connected. Moreover, a source of an i-th transistor 620_{—}i is electrically connected to a drain of an (i+1)-th transistor 620_(i+1), a drain of a 1st transistor 620_1 is electrically connected to a second power voltage VD₆₂, and a source and a gate of an X-th transistor 620_X are electrically connected to a node N61, where i is an integer and 1≦i≦(X−1).

On the other hand, gates of the transistors 630_1-630_Y are electrically connected. Moreover, a source of a j-th transistor 630_{—}j is electrically connected to a drain of a (j+1)-th transistor 630_(j+1), and a drain of the 1st transistor 630_1 is electrically connected to the node N61. Moreover, gates of the transistors 640_1-640_Z are electrically connected. Moreover, a source of a k-th transistor 640_{—}k is electrically connected to a drain of a (k+1)-th transistor 640_(k+1), a drain and a gate of the 1st transistor 640_1 are electrically connected to a source of the transistor 630_Y, and a source of a Z-th transistor 640_Z is electrically connected to a second ground voltage VS₆₂, where k is an integer and 1≦k≦(Z−1).

Similar to the embodiment of FIG. 4, the voltage divider 610 is electrically connected between a first power voltage VD₆₁ and a first ground voltage VS₆₁, and adjusts a level of a sensing voltage V₆₁ according to a variation of the first power voltage VD₆₁. When the sensing voltage V₆₁ is gradually increased and is higher than a trip point voltage, the transistors 630_1-630_Y are turned on, so that a level of a node voltage V₆₂ is pulled down to approach the second ground voltage VS₆₂. On the other hand, when the sensing voltage V₆₁ is gradually decreased and is lower than the trip point voltage, the transistors 630_1-630_Y are turned off, so that the level of the node voltage V₆₂ is pulled up to approach the second power voltage VD₆₂. Moreover, the inverter 650 is mainly used to provide a logic signal inverted to the node voltage V₆₂. Therefore, in an actual application, those skilled in the art can determine whether or not to use the inverter 650 according to an actual design requirement.

Moreover, the POR circuit 600 of the present embodiment still takes the trip point voltage as a reference to compare the sensing voltage V₆₁, and an equation of the trip point voltage VP₆ of the present embodiment can be deduced as a following equation (4-1) according the deduction flow of the embodiment of FIG. 4:

$${VP}_{6} = 3 \times {V}_{t , ENH} + ( \sqrt{\frac{\frac{{W}_{620}}{( X \times {L}_{620} )}}{\frac{{W}_{630}}{( Y \times {L}_{630} )}}} + \sqrt{\frac{\frac{{W}_{630}}{( X \times {L}_{620} )}}{\frac{{W}_{640}}{( Z \times {L}_{640} )}}} ) \times {V}_{t , DEP} \qquad ( 4 \text{-} 1 )$$

Where, V_{t,ENH} is a threshold voltage of the enhancement type n-channel transistor, and V_{t,DEP} is a threshold voltage of the depletion type n-channel transistor. W₆₂₀ and L₆₂₀ are respectively a width and a length of the conductive channel of each of the transistors 620_1-620_X, W₆₃₀ and L₆₃₀ are respectively a width and a length of the conductive channel of each of the transistors 630_1-630_Y, and W₆₄₀ and L₆₄₀ are respectively a width and a length of the conductive channel of each of the transistors 640_1-640_Z.

Referring to the equation (4-1), it is known that since the threshold voltage V_{t,DEP} of the depletion type transistor has a positive temperature coefficient and the threshold voltage V_{t,ENH} of the enhancement type transistor has a negative temperature coefficient, by adjusting the widths and the lengths of the conductive channels of the transistors, the trip point voltage VP₆ of the present embodiment may have the characteristic of non-related to temperature. In this way, the present embodiment can reduce influence of temperature to the circuit, and avails reducing a layout area and production cost of the circuit.

It should be noticed that according to the spirit of the embodiment of FIG. 4, a plurality of diode-connection type single transistors can be connected in series between the source of the transistor 440 and the second ground voltage VS₄₂ of FIG. 4. Moreover, according to the spirits of the embodiments of FIG. 5 and FIG. 6, the diode-connection type signal transistor can also be formed by a plurality of transistors connected in series.

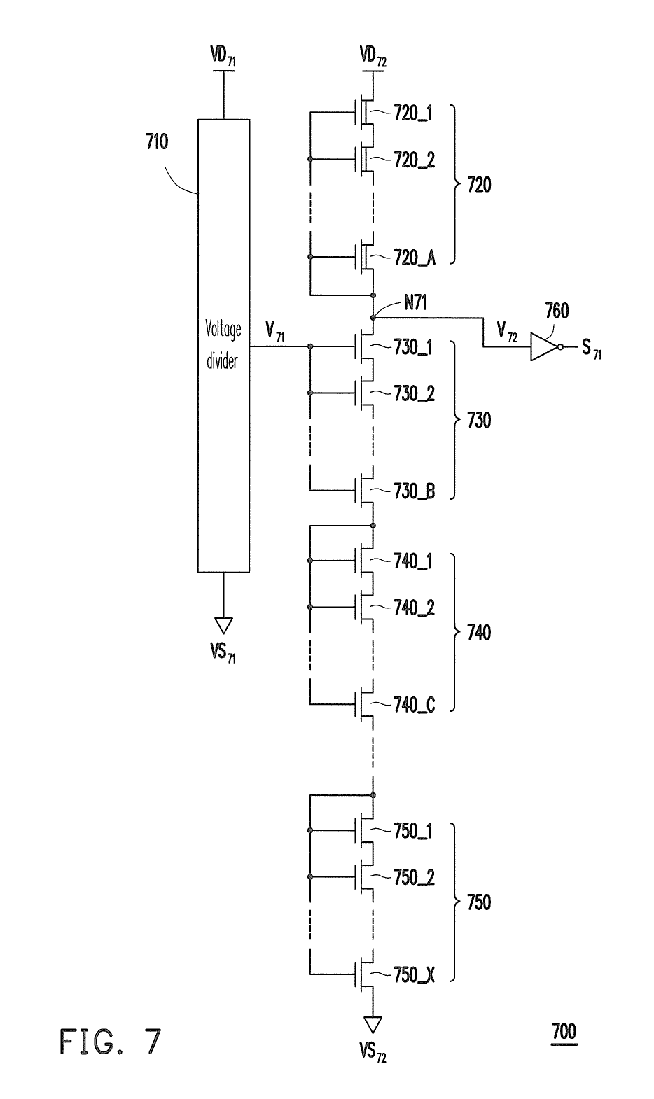

For example, FIG. 7 is a circuit diagram of a POR circuit according to still another embodiment of the invention. Referring to FIG. 7, the POR circuit 700 includes a voltage divider 710, A transistors 720_1-720_A, B transistors 730_1-730_B, C transistors 740_1-740_C, . . . , X transistors 750_1-750_X, and an inverter 760, where A, B, C, . . . , X are integers greater than 1. The transistors 720_1-720_A are equivalent to a transistor string 720, transistors 730_1-730_B are equivalent to a transistor string 730, and transistor stings 740-750 are deduced by analogy, and the POR circuit 700 includes N transistor strings, where N is an integer greater than 3.

The present embodiment is an extension of the embodiment of FIG. 6. The transistor string 720 is equivalent to the transistors 620_1-620_X in FIG. 6, the transistor string 730 is equivalent to the transistors 630_1-630_Y in FIG. 6, and the transistor string 740 is equivalent to the transistors 640_1-640_Z in FIG. 6. Moreover, a main difference between the present embodiment and the embodiment of FIG. 6 is that in the present embodiment, more transistor strings are connected in series behind the transistor string 740, for example, the transistor string 750.

Here, a trip point voltage VP₇ of the present embodiment is deduced as a following equation (5-1) according to deduction flows of the above embodiments:

$${VP}_{7} = ( N - 1 ) \times {V}_{t , ENH} + ( \sqrt{\frac{\frac{{W}_{720}}{( A \times {L}_{720} )}}{\frac{{W}_{730}}{( B \times {L}_{730} )}}} + \sqrt{\frac{\frac{{W}_{720}}{( A \times {L}_{720} )}}{\frac{{W}_{740}}{( C \times {L}_{740} )}}} ) + … + \sqrt{\frac{\frac{{W}_{720}}{( A \times {L}_{720} )}}{\frac{{W}_{750}}{( X \times {L}_{750} )}}} \times {V}_{t , DEP} \qquad ( 5 \text{-} 1 )$$

Where, V_{t,ENH} is a threshold voltage of the enhancement type n-channel transistor, and V_{t,DEP} is a threshold voltage of the depletion type n-channel transistor. W₇₂₀ and L₇₂₀ are respectively a width and a length of the conductive channel of each of the transistors 720_1-720_A, W₇₃₀ and L₇₃₀ are respectively a width and a length of the conductive channel of each of the transistors 730_1-730_B, W₇₄₀ and L₇₄₀ are respectively a width and a length of the conductive channel of each of the transistors 740_1-740_C, and W₇₅₀ and L₇₅₀ are respectively a width and a length of the conductive channel of each of the transistors 750_1-750_X.

Here, if the lengths and widths of the conductive channels of the transistors 720_1-720_A, 730_1-730_B, 740_1-740_C, . . . , 750_1-750_X are all the same, and A=B=C= . . . =X, the equation (5-1) can be simplified as a following equation (5-2):

VP₇=(N−1)×(V_{t,ENH}+V_{t,DEP}) (5-2)

Referring to the equation (5-2), it is known that since the threshold voltage V_{t,DEP} of the depletion type transistor has a positive temperature coefficient and the threshold voltage V_{t,ENH} of the enhancement type transistor has a negative temperature coefficient, the trip point voltage VP₇ of the present embodiment may have the characteristic of non-related to temperature, so as to reduce influence of temperature to the circuit. Moreover, in an actual application, the numbers of the transistors A, B, C, . . . , X can be different, and the lengths and the widths of the conductive channels of the transistors can also be different. In other words, those skilled in the art can arbitrarily adjust the lengths and the widths of the conductive channels and the numbers of the transistors according to an actual design requirement, so as to facilitate adjustment of the trip point voltage VP₇ and the temperature coefficient. On the other hand, the POR circuit 700 of the present embodiment avails reducing a layout area and production cost of the circuit. Detailed operation principles of the present embodiment have been described in the above embodiments, so that detailed descriptions thereof are not repeated.

In summary, in the invention, transistors with the same conductive channel and different types are used to generate a trip point voltage non-related to temperature. Moreover, the POR circuit of the invention compares the sensing voltage proportional to the power voltage according to the trip point voltage non-related to temperature. In this way, the POR circuit of the invention can reduce influence of temperature to the circuit, and avails reducing a layout area and production cost of the circuit.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A power-on reset circuit, comprising:
a voltage divider, electrically connected between a first power voltage and a first ground voltage, for generating a sensing voltage;
a first transistor, having a drain electrically connected to a second power voltage, and a gate and a source electrically connected to each other; and
a second transistor, having a same conductive channel and a different type with that of the first transistor, wherein a drain of the second transistor is electrically connected to the source of the first transistor, a gate of the second transistor receives the sensing voltage, and a source of the second transistor is electrically connected to a second ground voltage.

2. The power-on reset circuit as claimed in claim 1, further comprising:
an inverter, electrically connected to the drain of the second transistor.

3. The power-on reset circuit as claimed in claim 1, further comprising:
a third transistor, having a conductive channel and a type the same to that of the second transistor, wherein a drain and a gate of the third transistor are electrically connected to the source of the second transistor, and a source of the third transistor is electrically connected to the second ground voltage.

4. The power-on reset circuit as claimed in claim 1, wherein the first power voltage is equal to the second power voltage, and the first ground voltage is equal to the second ground voltage.

5. The power-on reset circuit as claimed in claim 1, wherein a length of the conductive channel of the first transistor is equal to a length of the conductive channel of the second transistor, and a width of the conductive channel of the first transistor is equal to a width of the conductive channel of the second transistor.

6. A power-on reset circuit, comprising:
a voltage divider, electrically connected between a first power voltage and a first ground voltage, for generating a sensing voltage;
X first transistors, having gates electrically connected to each other, wherein a drain of a 1st first transistor is electrically connected to a second power voltage, a source of an i-th first transistor is electrically connected to a drain of an (i+1)-th first transistor, and a source and a gate of an X-th first transistor are electrically connected to a node, wherein X is an integer greater than 1, i is an integer and 1≦i≦(X−1); and
Y second transistors, having same conductive channels and a different type with that of the X first transistors, wherein gates of the second transistors are electrically connected and receive the sensing voltage, a drain of a 1st second transistor is electrically connected to the node, a source of a j-th second transistor is electrically connected to a drain of a (j+1)-th transistor, and a source of a Y-th second transistor is electrically connected to a second ground voltage, wherein Y is an integer greater than 1, j is an integer and 1≦j≦(Y−1).

7. The power-on reset circuit as claimed in claim 6, further comprising:
an inverter, electrically connected to the node.

8. The power-on reset circuit as claimed in claim 6, further comprising:
Z third transistors, having conductive channels and a type the same to that of the second transistors, wherein gates of the third transistors are electrically connected, a drain and a gate of a 1st third transistor are electrically connected to the source of the Y-th second transistor, a source of a k-th third transistor is electrically connected to a drain of a (k+1)-th third transistor, and a source of a Z-th third transistor is electrically connected to the second ground voltage, wherein Z is an integer greater than 1, k is an integer and 1≦k≦(Z−1).

9. The power-on reset circuit as claimed in claim 6, wherein the first power voltage is equal to the second power voltage, and the first ground voltage is equal to the second ground voltage.

10. The power-on reset circuit as claimed in claim 6, wherein lengths and widths of the conductive channels of the first transistors and the second transistors are equivalent.
